(19) United States
(12) Patent Application Publication
(10) Pub. No.: US 2009/0308650 A1
(43) Pub. Date: Dec. 17, 2009

(54) Printed circuit board and method of manufacturing the same

(75) Inventors: Eung Suek Lee, Gyunggi-do (KR); Je Gwang Yoo, Gyunggi-do (KR); Chang Sup Ryu, Gyunggi-do (KR); Jun Oh Hwang, Gyunggi-do (KR); Jun Heyoung Park, Gyunggi-do (KR); Jee Soo Mok, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/222,176

(22) Filed: Aug. 4, 2008

(30) Foreign Application Priority Data
Jun. 13, 2008 (KR) 10-2008-0055783

(51) Int. Cl. H05K 3/06; H05K 1/09

(52) U.S. Cl. 174/261; 216/13; 29/846

(57) ABSTRACT

The printed circuit board is manufactured using a simple process of forming a bump on a first metal layer using fireable paste containing carbon nanotubes, firing the first metal layer including the bump, forming an insulating layer and a second metal layer on the first metal layer, and patterning the first and second metal layers, thus specific resistance of the resulting printed circuit board is decreased, and electrical conductivity and cooling performance are improved.

### CROSS REFERENCE TO RELATED APPLICATION

This application claims the benefit of Korean Patent Application No. 10-2008-0055783, filed Jun. 13, 2008, entitled “PRINTED CIRCUIT BOARD AND A FABRICATING METHOD OF THE SAME”, which is hereby incorporated by reference in its entirety into this application.

### BACKGROUND OF THE INVENTION

1. Field of the Invention

The present invention relates generally to a printed circuit board and a method of manufacturing the printed circuit board, and, more particularly, to a printed circuit board including a bump which is made of fireable paste containing carbon nanotubes or carbon nanofiber, and a method of manufacturing the printed circuit board.

2. Description of the Related Art

These days, in response to the widening of the functionality and the miniaturization of electronic products, printed circuit boards, on which such electronic products are mounted, are being required to have a high density. As a technology for satisfying the above requirement, an intensive research on an electrical interlayer connection technology of a circuit pattern is being actively conducted.

These days, as an electrical interlayer connection technology of a circuit pattern, a method of conducting an interlayer connection using a laser via and a method of conducting an interlayer connection using conductive paste bumps are being commercially used.

Among these, the method of conducting an interlayer connection using a laser via is configured in a manner such that a via-hole is formed in an insulating layer using CO₂ laser or UV laser, and the via-hole is plated with a metal plating layer for the interlayer connection, and the method of conducting an interlayer connection using conductive paste bumps is configured in a manner such that a copper film is printed with conductive paste such as silver (Ag) to form a conical bump, and prepreg is perforated by the conical bump and is then pressed in conjunction with the copper film for the interlayer connection.

However, since the interlayer connection method using a laser via uses a variety of chemicals to form a plating layer, it induces environmental problems and increase of cost. In addition, the method has a problem in that the drilling operation for forming the via-hole causes extension of lead-time, thus obstructing the mass production.

Meanwhile, the interlayer connection method using conductive paste bumps has problems in that the interlayer connection part constructed using the conductive paste bumps has a specific resistance higher than an interlayer connection part constructed using copper plating and has inferior electrical conductivity due to a polymer component in the paste composition.

Accordingly, in order to increase electrical conductivity while taking advantages in the interlayer method using conductive paste bumps, an intensive research is being actively conducted on a method of conducting an interlayer connection using carbon nanotubes which have an maximum allowable current as high as about 1000 times copper material.

In a conventional process, carbon nanotubes are brought to vertically grow on a silicon substrate through chemical vapor deposition (CVD) for the interlayer connection. FIGS. 1 to 4 are cross-sectional views showing a conventional process of forming carbon nanotubes on a silicon substrate for the interlayer connection.

As shown in FIG. 1, nano-sized catalytic metal particles 12 are first deposited on a silicon substrate 11, and then an insulating layer 13 is formed on the catalytic metal particle layer.

As shown in FIG. 2, via-holes 14 are formed in the insulating layer 13 using laser.

As shown in FIG. 3, carbon nanotubes 15 are brought to vertically grow in the via-holes 14 by conducting chemical vapor deposition at a high temperature of 500-1000° C.

As shown in FIG. 4, a copper layer 16 is deposited on the insulating layer 13 such that the copper layer 16 is electrically connected to the carbon nanotubes 15, thus enabling the carbon nanotubes 15 to serve as interlayer connection means.

However, in order to form the carbon nanotubes 15 according to the conventional process, the chemical vapor deposition, which is conducted at a temperature of about 500-4000° C., is required. Consequently, in order to enable the carbon nanotubes 15 to vertically grow, base material, which can be used even at high temperature, for example base material like the silicon substrate 11 is required, and manufacturing time and manufacturing costs are increased and the manufacturing process becomes complicated.

In addition, there are other problems in that a separate catalytic layer 12 is required, and also a special container having high hermetic ability is required in order to form the nano-sized metal particle layer 12 on the silicon substrate 11, thus increasing costs of the manufacturing facilities.

Such a process of forming carbon nanotubes through the chemical vapor deposition is not so suitable for the indirect application to a manufacturing process of a printed circuit board.

### SUMMARY OF THE INVENTION

Accordingly, the present invention has been made keeping in mind the above problems occurring in the prior art, and the present invention provides a printed circuit board, in which a bump made of fireable paste containing carbon nanotubes or carbon nanofiber is used for the interlayer connection, and a method of manufacturing the printed circuit board.

In one aspect, the present invention provides a printed circuit board including: an insulating layer; first and second circuit layers formed on both sides of the insulating layer; and a bump made of fireable paste containing carbon nanotubes, which is disposed between the first and second circuit layers for the electrical connection therebetween.

The bump may include the carbon nanotubes or carbon nanofiber and metal microparticles.

The metal microparticles may include silver (Ag).

The printed circuit board may further include a buildup layer including a buildup insulating layer and a buildup circuit layer, formed the first and/or second circuit layer.

The buildup circuit layer and the first and/or second circuit layer may be interconnected to each other via a buildup bump containing made of fireable paste containing carbon nanotubes.

In another aspect, the present invention provides a method of manufacturing a printed circuit board, including: forming a bump on a first metal layer using fireable paste containing carbon nanotubes; firing the first metal layer including the bump formed thereon; forming an insulating layer on the first metal layer including the bump formed thereon; forming a second metal layer on the insulating layer such that the second metal layer is electrically connected to the bump; and patterning the first metal layer and the second metal layer to form a first circuit layer and a second circuit layer.

The fireable paste may include the carbon nanotubes or carbon nanofiber, metal microparticles and binder.

The metal microparticles may include silver (Ag).

The binder may be removed by the firing of the first metal layer.

The method may further include, after the firing the first metal layer, removing residual binder, which is not removed but still remains even through the firing, using a reactive ion etching (RIE) process.

The method may further include, after the firing the first metal layer, conducting a picking to remove oxide formed on the first metal layer through the firing.

The method may further include, after the patterning the first and second metal layers, forming a buildup layer including a buildup insulating layer and a buildup circuit layer, on the first and/or second circuit layer.

The buildup circuit layer and the first and/or second circuit layer may be interconnected to each other via a bump made of fireable paste containing carbon nanotubes.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 4 are cross-sectional views illustrating a conventional process of forming carbon nanotubes on a printed circuit board for the interlayer connection;

FIG. 5 is a cross-sectional view of a printed circuit board according to an embodiment of the present invention;

FIG. 6 is a flowchart illustrating a process of manufacturing a printed circuit board, according to an embodiment of the present invention; and

FIGS. 7 to 13 are cross-sectional views illustrating a process of manufacturing a printed circuit board, according to an embodiment of the present invention.

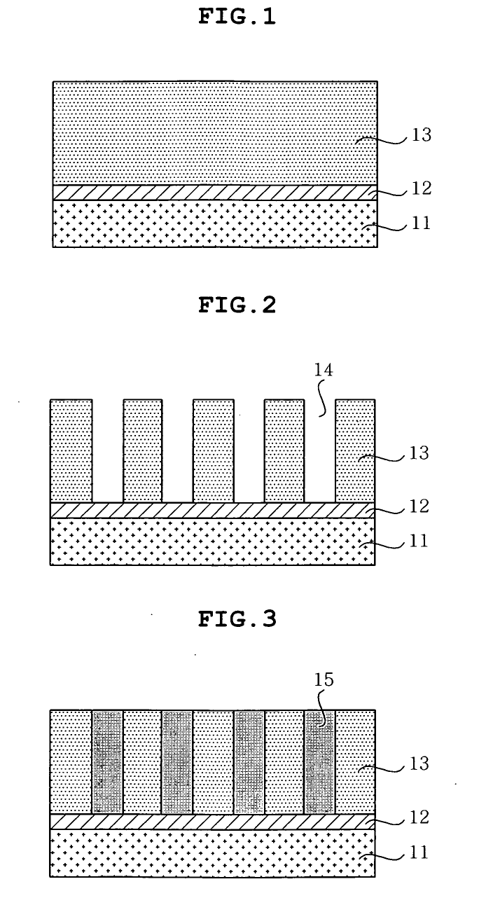

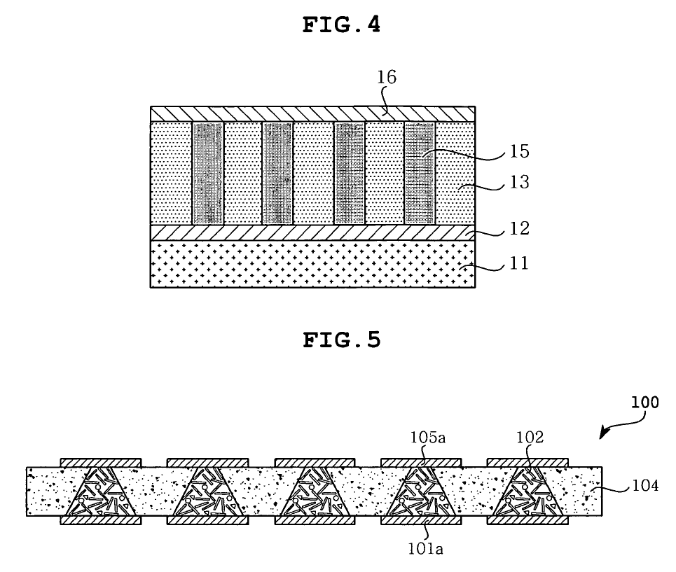

### DESCRIPTION OF THE PREFERRED EMBODIMENTS

Various objects, advantages and features of the invention will become apparent from the following description of embodiments with reference to the accompanying drawings. In the designation of reference numerals, it should be noted that the same reference numerals are used throughout the different drawings to designate the same or similar components. Also, in the description of the present invention, when it is considered that the detailed description of a related prior art may obscure the gist of the present invention, such detailed description is omitted.

Hereinafter, an embodiment of the present invention will be described in greater detail with reference to the following drawings.

FIG. 5 is a cross-sectional view showing a printed circuit board according to an embodiment of the present invention. Referring to FIG. 5, a printed circuit board 100 according to the embodiment of the present invention is now described.

The printed circuit board according to an embodiment of the present invention comprises an insulating layer 104, a first circuit layer 101a formed on the lower surface of the insulating layer 104, a second circuit layer 105a formed on the upper surface of the insulating layer 104, and bumps disposed between the first circuit layer 101a and the second circuit layer 105a for the electrical connection therebetween and made of fireable paste containing carbon nanotubes.

In this regard, the bumps 102 include carbon nanotubes or carbon nanofiber, metal microparticles, additive and the like. As can be appreciated from Table 1 below, the carbon nanotubes or the carbon nanofiber has electrical properties, which is superior to metal materials such as aluminum or copper having relatively excellent electrical conductivity and specific resistance, thus improving the reliability of interlayer connection and the cooling efficiency.

TABLE 1

| Physical properties | carbon nanotube | comparative materials |
|---|---|---|
| density | 1.33~1.40 g/cm³ | 2.7 g/cm³ |
| Current density | 1 × 10⁹ A/cm² | 1 × 10⁶ A/cm²(copper cable) |
| thermal conductivity | 6000 W/mK | 400 W/mk(copper) |
| specific resistance | 1 × 10⁻¹⁰ · Ω · cm | 1 × 10⁻¹⁰ · Ω · cm(copper) |

Although the carbon nanotubes may be comprised of either or both single-walled carbon nanotubes and multi-walled carbon nanotubes, the multi-walled carbon nanotubes, which have electrical conductivity proportional to a diameter thereof, may be used in this embodiment.

The metal microparticles, which may be comprised of high conductive silver (Ag) microparticles, copper (Cu) microparticles or a proper combination thereof, function to increase adhesiveness and electrical conductivity.

The additive, which is an element for controlling adhesiveness and printability, may be composed of one or more selected from among organic/inorganic filler, dye, pigment, thickener, lubricant agent, defoaming agent, dispersing agent, levelling agent, flame retardant, thixotropic agent, brightener, coupling agent which includes a hydrophobic functional group capable of being coupled to resin in molecules as well as a hydrophilic functional group capable of being coupled to inorganic filler. The inorganic filler, which functions to lower a coefficient of thermal expansion, may include spherical/platy/amorphous silica, alumina, diatomous earth and the like. The additive may include an oxide additive, such as pine tar, to eliminate oxides.

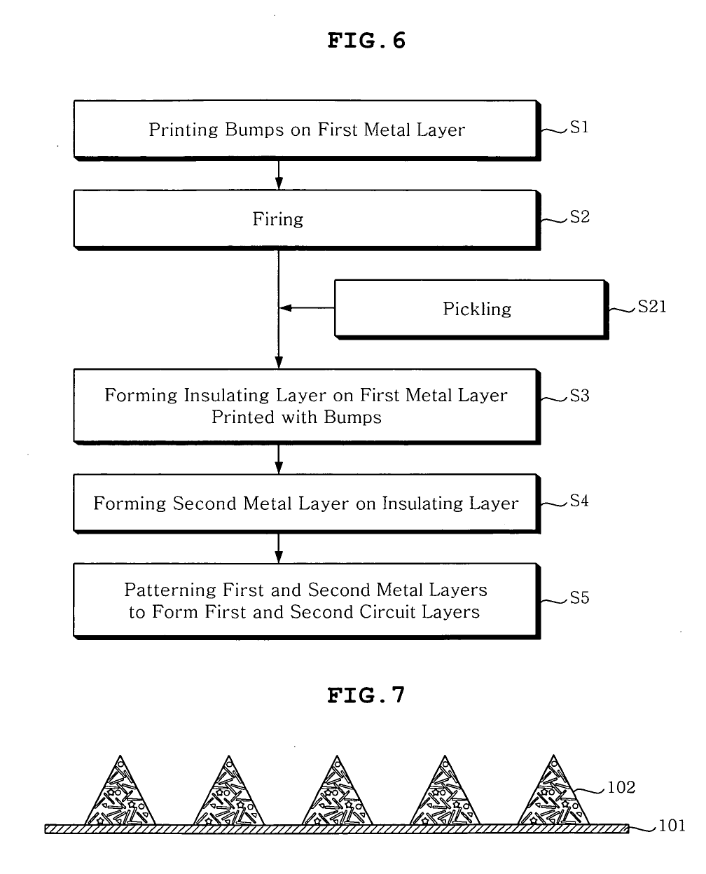

FIG. 6 is a flowchart illustrating a process of manufacturing a printed circuit board, according to an embodiment of the present invention, and FIG. 7 to 13 are cross-sectional views illustrating the process of manufacturing a printed circuit board, according to an embodiment of the present invention.

First, S1 is an operation of printing a bump 102 on a first metal layer 101 using fireable paste containing carbon nanotubes, which is illustrated in FIG. 7.

At this point, the bumps 102 may also be printed through a screen print technology. The screen print technology is conducted in a manner such that conductive paste is transferred to the first metal layer through a mask having openings. More specifically, after the mask is arranged such that the openings are aligned, conductive paste is applied on the upper surface of the mask. Thereafter, the conductive paste is pressed using a squeegee so that the conductive paste is extruded through the openings of the mask and is thus transferred on the first metal layer 101, in which the conductive paste may be applied into any of desired patterns and heights. Of course, it should be noted that other known process of forming the bumps 102 also falls within the scope of the present invention.

The fireable paste containing a carbon nanotubes is composed of a mixture of binder and powdered carbon nanotubes or carbon nanofiber powder, and may further include metal microparticles, additives and the like.

In this embodiment, the fireable paste may comprise about 75-85 wt % of carbon nanotubes or carbon nanofiber, about 5-10 wt % of binder and about 5 wt % of additive. Herein, since the details of the carbon nanotubes or carbon nanofiber, the metal microparticles and the additive have been previously described above, the description is omitted herein.

The binder, which is intended to control elasticity and adhesivity of the fireable paste, may be used in a varying weight composition depending on need. For example, the binder may include one or more types of thermosetting resin, such as epoxy resin, cyanic acid ester resin, bismaleimide (BMI) resin, polyimide resin, benzocyclobutene (BCB) resin and phenol resin, thermoplastic resin, such as polyurethane resin, polyamideimide resin and polyphenylene ether resin, and UV curing resin. Furthermore, the binder may be selected from the group consisting of polyethylene oxide, polypropylene carbonate and a combination thereof. This allows firing at a low temperature and easy decomposition of the binder during the firing process, thus preventing deterioration of the carbon nanotubes or carbon nanofiber and improving thermal conductivity.

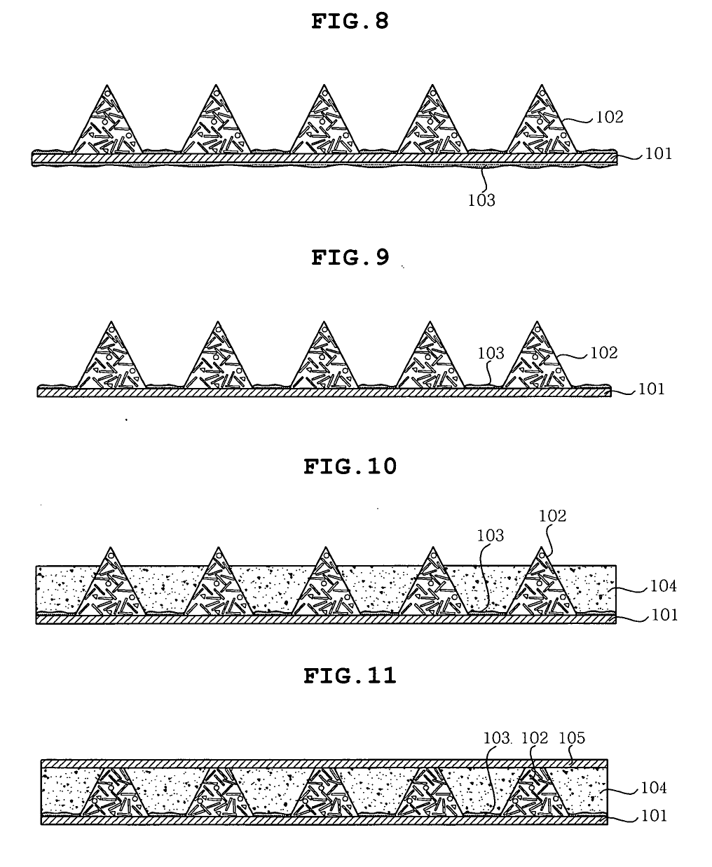

Subsequently, S2 is an operation of conducting a firing process, which is illustrated in FIG. 8.

At this point, as the fireable paste is heated to a temperature of 500° C. or higher during the firing process, the binder contained in the paste binds the carbon nanotubes or carbon nanofiber to each other and is then thermally decomposed and thus eliminated. As a result, the fireable paste bumps 102 are composed of a fired body containing carbon nanotubes or carbon nanofiber, metal microparticles and an additive.

However, when the binder still remains even after the firing process, a reactive ion etching (RIE) process for improvement of the cooling performance may be further conducted to eliminate the binder. The reactive ion etching process is referred to a technology which is conducted in such a manner as to react active species existing in plasma of reactive gas with atoms on the surface of an etching target material to generate volatile reaction products, and then separate the volatile reaction products from the surface of the etching target material. In this embodiment of the present invention, the reactive ion etching may be conducted through a dielectric barrier discharge (DBD) using inert gases such as argon (Ar) or helium (He).

S21 is an operation of conducting a pickling process, which is illustrated in FIG. 9. In this process, oxide scale 103, which is formed on the metal layer 101 during the firing process, is removed. This pickling process may be optionally conducted depending on need.

The pickling process, which is intended to remove oxide scale, may include salt bath treatment, mechanical descaling, electrolytic pickling, pickling using strong acid (sulfuric acid, nitric acid, etc.), and pickling using ultrasonic wave.

When the first metal layer 101, which has been printed with the bumps 102, is subjected to the firing process, the oxide scale 103 may be formed on the first metal layer 101. More specifically, since one side of the first metal layer 101, on which the bumps 102 have been formed, is provided with an insulating layer later and does not need an additional acid wash process whereas the other side of the metal layer 101, on which the bumps 102 have not been formed, is formed into a circuit layer, the oxide scale 103 may be removed using the acid wash process.

Thereafter, S3 is an operation of forming an insulating layer 104 on the first metal layer 101 including the bumps 102 formed thereon, which is illustrated in FIG. 10.

In this process, the insulating layer 104 may be configured in such a manner as to have a thickness less than the thickness of the bumps 102, and may be formed through a contact type process or a noncontact type process.

In the contact type process, the insulating layer 104 is formed and thus layered of the first metal layer 101 including the bumps 102. In this regard, the bumps 102 may have a strength higher than that of the insulating layer 104 such that the bumps 102 can perforate the insulating layer 104, and the insulating layer 104 may be semicured prepreg made of thermosetting resin. Since the insulating layer 104 has a thickness less than the thickness of the bumps 102, the bumps 102 perforates the insulating layer 104 and protrudes by a height corresponding to the difference between both the thicknesses.

Meanwhile, in the noncontact type process, the first metal layer 101 is coated with insulating resin powder through an inkjet printing technology. This noncontact type process is advantageous in that it is possible to minimize problems of the contact type process, such as deformation of the bumps 102 and minute clearances occurring between the bumps 102 and the insulating layer 104, which may be caused by the fact that the bumps 102 is thus subjected to external force while perforating the insulating layer 104.

S4 is an operation of applying a second metal layer 105 on the insulating layer 104, which is illustrated in FIG. 11.

In this operation, the second metal layer 105 is layered on the insulating layer 104 in a manner such that the insulating layer 104 and the bumps 102 become semicured by being heated to a softening temperature or higher and the second layer 105 is pressed onto the insulating layer 104 and the bumps 102 using a press plate such as a stainless plate having a flat surface. As such, by the pressing of the second metal layer 105, the second metal layer 105 is connected to the bumps 102.

Meanwhile, since the insulating layer 104 is pressed by the press plate having a flat surface so that the pressure of the press plate is uniformly applied to the insulating layer 104, it is possible to prevent warp or distortion of the entire substrate. Furthermore, since the insulating layer 104 is pressed in the vacuum atmosphere, there is no air bubble occurring in the insulating layer 104.

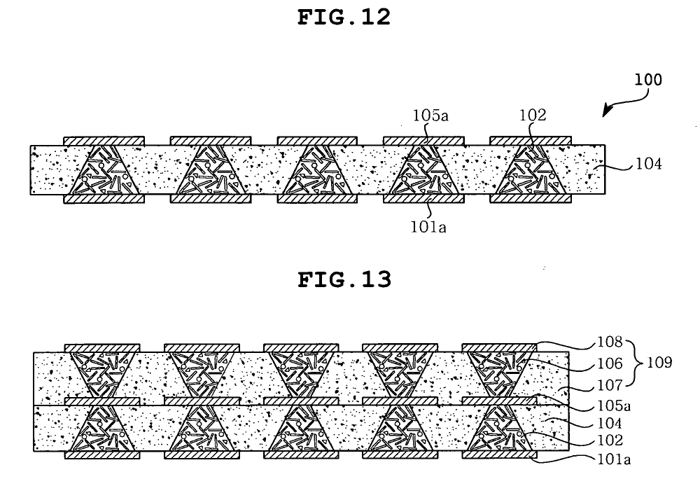

Subsequently, S5 is an operation of patterning the first metal layer 101 and the second metal layer 105 to form a first circuit layer 101a and a second circuit layer 105a, which is illustrated in FIG. 12.

In this operation, the first circuit layer 101a and the second circuit layer 105a may be formed using a usual process of forming a circuit layer, such as a subtractive process. That is, dry film (DF) layers are formed on the first metal layer 101 and the second metal layer 105, and then light exposure, development and etching processes are conducted thereon, thus forming the first circuit layer 101a and the second circuit layer 105a.

By the process which is conducted in above-described manner, a printed circuit board 100 is manufactured, as shown in FIG. 5.

Meanwhile, as shown in FIG. 13, in order to manufacture a multilayered printed circuit board, a buildup layer 109, which includes a buildup insulating layer 107 and a buildup circuit layer 108 may be formed on either or both the first circuit layer 101a and the second circuit layer 105a. At this point, the second circuit layer 105a and the buildup circuit layer 108 may be electrically connected to each other via a bumps 106 which are made of fireable paste containing carbon nanotubes.

In this regard, the buildup layer 109 may be formed in a manner such that a buildup insulating layer 107 is formed on a buildup metal layer, which is prepared through the process shown in FIGS. 7 to 10 and includes a buildup bumps 106 containing carbon nanotubes, the first circuit layer 101a and/or the second circuit layer 105a is disposed to face the buildup bumps 106 and then pressed thereto, and the buildup metal layer is patterned to form the buildup circuit layer 108. For convenience of explanation, although the buildup layer 109 is shown in FIG. 13 as being formed on the second circuit layer 105a, the buildup layer 109 may also be formed on the first circuit layer 101a, which should also be understood to falls within the scope of the present invention.

When the buildup bumps 106 are formed on the first circuit layer 101a and/or the second circuit layer 105a and they are subjected to a firing process, the insulating layer 104 can be removed at a high temperature. Accordingly, it is preferable to manufacture the printed circuit board using the above-describe layering process under pressure.

As described above, according to the present invention, circuit layers are connected through bumps made of fireable paste containing carbon nanotubes or carbon nanofiber, specific resistance of the resulting printed circuit board is decreased, and electrical conductivity and cooling performance are improved.

In addition, according to the present invention, an interlayer connection structure can be realized using carbon nanotubes or carbon nanofiber through a simple process.

Although the preferred embodiment of the present invention has been disclosed for illustrative purposes, those skilled in the art will appreciate that various modifications, additions and substitutions are possible, without departing from the scope and spirit of the invention as disclosed in the accompanying claims. Accordingly, the modifications, additions and substitutions should also be understood to fall within the scope of the present invention.

What is claimed is:

1. A printed circuit board comprising:
an insulating layer;
first and second circuit layers formed on both sides of the insulating layer; and
a bump made of fireable paste containing carbon nanotubes, which is disposed between the first and second circuit layers for the electrical connection therebetween.

2. The printed circuit board according to claim 1, wherein the bump includes the carbon nanotubes or carbon nanofiber and metal microparticles.

3. The printed circuit board according to claim 2, wherein the metal microparticles include silver (Ag).

4. The printed circuit board according to claim 1, further comprising a buildup layer including a buildup insulating layer and a buildup circuit layer, formed the first and/or second circuit layer.

5. The printed circuit board according to claim 4, wherein the buildup circuit layer and the first and/or second circuit layer are interconnected to each other via a buildup bump containing made of fireable paste containing carbon nanotubes.

6. A method of manufacturing a printed circuit board, comprising:
forming a bump on a first metal layer using fireable paste containing carbon nanotubes;
firing the first metal layer including the bump formed thereon;
forming an insulating layer on the first metal layer including the bump formed thereon;
forming a second metal layer on the insulating layer such that the second metal layer is electrically connected to the bump; and
patterning the first metal layer and the second metal layer to form a first circuit layer and a second circuit layer.

7. The method according to claim 6, wherein the fireable paste includes the carbon nanotubes or carbon nanofiber, metal microparticles and binder.

8. The method according to claim 7, wherein the metal microparticles include silver (Ag).

9. The method according to claim 6, wherein the binder is removed by the firing of the first metal layer.

10. The method according to claim 6, further comprising, after the firing the first metal layer, removing residual binder, which is not removed but still remains even through the firing, using a reactive ion etching (RIE) process.

11. The method according to claim 6, further comprising, after the firing the first metal layer, conducting a pickling to remove oxide formed on the first metal layer through the firing.

12. The method according to claim 6, further comprising, after the patterning the first and second metal layers, forming a buildup layer including a buildup insulating layer and a buildup circuit layer, on the first and/or second circuit layer.

13. The method according to claim 12, wherein the buildup circuit layer and the first and/or second circuit layer are interconnected to each other via a bump made of fireable paste containing carbon nanotubes.
